(19) United States
(12) Patent Application Publication
(10) Pub. No.: US 2001/0017392 A1
(43) Pub. Date: Aug. 30, 2001

(54) Vertical transport MOSFETs and method for making the same

(75) Inventors: James Hartfiel Comfort, New City, NY (US); Young Hoon Lee, Somers, NY (US); Yaun Taur, Bedford, NY (US); Samuel Jonas Wind, White Plains, NY (US); Hom-Sum Philip Wong, Chappagua, NY (US)

Correspondence Address: HARTMAN & HARTMAN, P.C., 552 EAST 700 NORTH, VALPARAISO, IN, 46383, US

(73) Assignee: International Business Machines Corporation.

(21) Appl. No.: 09/814,514

(22) Filed: Mar. 22, 2001

Related U.S. Application Data
(62) Division of application No. 08/858,236, filed on May 19, 1997, now abandoned.

(51) Int. Cl. H01L 21/336; H01L 29/76; H01L 29/94; H01L 31/062; H01L 31/113; H01L 31/119

(52) U.S. Cl. 257/410; 257/374; 438/269

(57) ABSTRACT

MOSFET comprising:

a first semiconductor region formed in the semiconductor substrate on which the MOSFET is to be integrated, said region being defined in said semiconductor substrate by n+-type doping,

a thin and short semiconductor channel being arranged perpendicular with respect to said substrate, said channel being in homo-epitaxial alignment with said first semiconductor region,

a gate oxide layer formed on said semiconductor channel,

a second semiconductor region formed at the opposite end of said semiconductor channel, said region being n+ doped and in homo-epitaxial alignment with said semiconductor channel,

at least one gate electrode arranged between said first and second semiconductor regions such that it is separated from said semiconductor gate channel by a gate oxide layer,

said first semiconductor region serving as drain and said second semiconductor region serving as source, or vice versa.

### TECHNICAL FIELD

The present invention concerns metal-oxide-semiconductor field effect transistors (MOSFETs) having a vertical transport gate channel.

### BACKGROUND OF THE INVENTION

In order to be able to make memory chips and logic devices of higher integration density than currently feasible, one has to find a way to further scale down the silicon MOSFETs used in such chips and devices. The scaling of silicon MOSFETs to their theoretically predicted miniaturization limits cannot be accomplished by simply shrinking all device features of the MOSFET to specified dimensions. New device features are required. The gate length and thickness are of particular concern if one tries to further miniaturize these MOSFETs.

Frank et al. have modeled a horizontal dual gate MOSFET device which extends the theoretical scaling limit to gate lengths as short as 30 nm. This MOSFET, as modeled by Frank et al., is described in “Monte Carlo Simulation of a 30 nm Dual-gate MOSFET: How Short Can Si Go?”, IEDM Technical Digest, pp. 553-556.

The device 10, as modeled by Frank et al, is schematically illustrated in FIG. 1. It has two gate electrodes 11 and 12. These gate electrodes 11 and 12 are partially enclosed by SiO sub 2 oxide layers 13 and 14. These oxide layers 13 and 14 embed a silicon gate channel 15 having a thickness d sub C and a length I sub G. The MOSFET 10 furthermore comprises a drain electrode 16 and a source electrode 17, both consisting of n+ doped silicon. The silicon channel 15 Frank et al. modeled is as thin as 5 nm.

There are currently no MOSFET fabrication schemes known that would allow to realize the modeled MOSFET 10. None of the currently employed fabrication schemes would result in a dual gate MOSFET structure with a channel as thin as 5 nm, as required by the theoretical model.

Dual gate MOSFET devices as such are known in the art. An example is disclosed and described in U.S. Pat. No. 5,461,250. It is to be noted, however, that the dual gate MOSFET described therein is arranged horizontally.

In co-pending U.S. patent application Ser. Nos. 08/554,558 and 08/634,342 a vertical MOSFET in the form of a pillar with source, drain, gate and channel regions is described. This MOSFET is a dual gate field effect transistor comprising a first region of first semiconductor material having a first conductivity type forming a source, a second region of second semiconductor material having a second conductivity type forming a channel, and a third region of third semiconductor material having the first conductivity type forming a drain. The first and third semiconductor materials may be of the same or different materials but both are different from the second semiconductor material to form a heterojunction between the channel and the source and drain. First and second gate regions are positioned on the first and second sidewalls respectively of the channel region.

It is an object of the present invention to provide MOSFETs having an ultrathin channel.

It is a further object of the present invention to provide a MOSFET structure which is suited for integration at high density.

It is another object of the present invention to provide dual gate MOSFETs suited for integration at high density.

It is an object of the present invention to provide a method for making such MOSFETs.

### SUMMARY OF THE INVENTION

The above objectives have been accomplished by the provision of a vertical arrangement of the gate channel and the different features making up a MOSFET. The MOSFETs disclosed and claimed herein comprise:

a first semiconductor region formed in the semiconductor substrate on which the MOSFET is to be integrated, said region being defined in said semiconductor substrate by n+-type doping,

a thin and short semiconductor channel being arranged perpendicular with respect to said substrate, said channel being in homo-epitaxial alignment with said first semiconductor region,

a gate oxide layer formed on said semiconductor channel,

a second semiconductor region formed at the opposite end of said semiconductor channel, said region being n+ doped and in homo-epitaxial alignment with said semiconductor channel,

at least one gate electrode arranged between said first and second semiconductor regions such that it is separated from said semiconductor gate channel by a gate oxide layer,

said first semiconductor region serving as drain and said second semiconductor region serving as source, or vice versa.

The above vertical MOSFET structure can be integrated into a semiconductor substrate by the following steps:

defining a first semiconductor region in the substrate in which the MOSFET is to be integrated by n+ type doping,

covering at least part of said first semiconductor region by a first layer the thickness of which approximately defines the length of the semiconductor gate channel to be formed,

defining an etch window in said first layer, the width of which corresponds to the thickness of said semiconductor gate channel to be formed and the depth of which corresponds to the length of said semiconductor gate channel to be formed,

forming said semiconductor gate channel by filling up said etch window with a semiconductor such that said channel is in homo-epitaxial alignment with said first semiconductor region,

forming a n+-doped second semiconductor region on top of said semiconductor gate channel, said second semiconductor region partially overlapping said first layer and being in homo-epitaxial alignment with said first semiconductor region,

removing at least part of said first layer and said dielectric layer such that said semiconductor gate channel and the surfaces of said first and second semiconductor regions which face each other become accessible,

forming a thin gate oxide covering the vertical surface of said semiconductor gate channel and at least part of the horizontal surfaces of said first and second semiconductor regions which face each other,

forming at least one gate electrode such that it adjoins to said gate oxide.

The above process can be modified in different ways.

If the dimension of the etch window is so small that the available processes can not be used anymore for the definition thereof, an etch window of larger width can be made. This etch window then may be narrowed down by the use of a sidewall formation process. After sidewall formation, the etch window then has reached the desired width, namely the width corresponds to the thickness of said semiconductor gate channel to be formed.

It is to be noted that a similar structure can be realized with said first and second semiconductor regions being p+ doped.

In addition to the above general embodiments, other examples for the implementation of the present invention will be given. The structures herein described and claimed have the following advantageous properties:

vertical charge transport,

easy realization of single and dual gate structures and any combination of both,

ultrashort gate channel,

ultrathin gate channel,

the inventive MOSFET structures are self-aligned, i.e., just a single level of high resolution lithography is required,

easy CMOS integration of n-type and p-type MOSFETs within the same substrate.

Further advantages will become obvious form the detailed description and the drawings.

### DESCRIPTION OF THE DRAWINGS

The invention is described in detail below with reference to the following schematic drawings:

FIG. 1 is a schematic cross section of a dual gate MOSFET as modelled by Frank et al.

FIG. 2 is a schematic cross section of the basic structure of a vertical transport dual gate MOSFET, according to the present invention.

FIG. 3 shows the key steps of a suggested fabrication sequence for fabrication of the inventive vertical transport dual gate MOSFET.

FIG. 3A shows the substrate with a heavily doped first region covered by a dielectric layer.

FIG. 3B shows the mask used to define the selective epitaxy growth of the channel.

FIG. 3C shows an etch window formed in the dielectric layer by lithography and Reactive Ion Etching (RIE).

FIG. 3D shows the etch window after it has been narrowed by the formation of a sidewall.

FIG. 3E shows the undoped gate channel grown by selective epitaxy.

FIG. 3F shows the heavily doped second region formed on top of said gate channel.

FIG. 3G shows the device structure after the dielectric layer was removed.

FIG. 3H shows the device structure after a thin gate oxide has been formed.

FIG. 3I shows the device structure after formation of the gate electrode(s).

FIG. 4A shows a schematic cross section of another embodiment of the present invention.

FIG. 4B shows a schematic top view of the device in FIG. 4A.

FIG. 5 shows a CMOS implementation of the vertical dual gate MOSFET, according to the present invention, with two adjacent devices, one n-type and the other p-type.

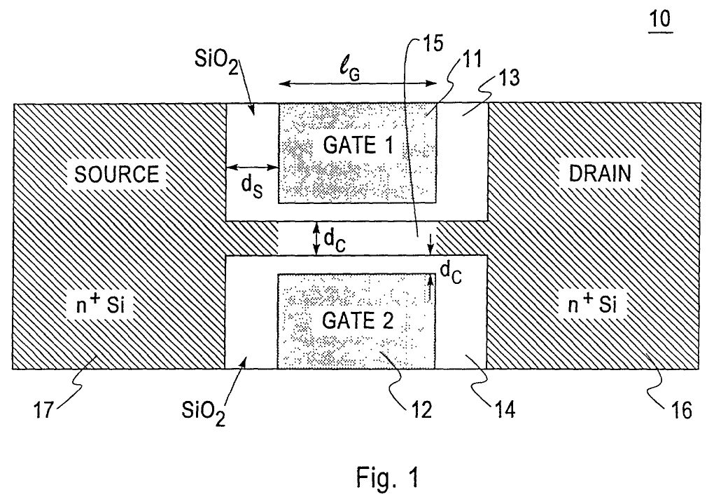

### DESCRIPTION OF PREFERRED EMBODIMENT

In the present context, n+ or p+ doped semiconductors are meant to be heavily doped semiconductors. They typically have a concentration of dopants of at least 10¹⁸ to 10²²/cm sup 3.

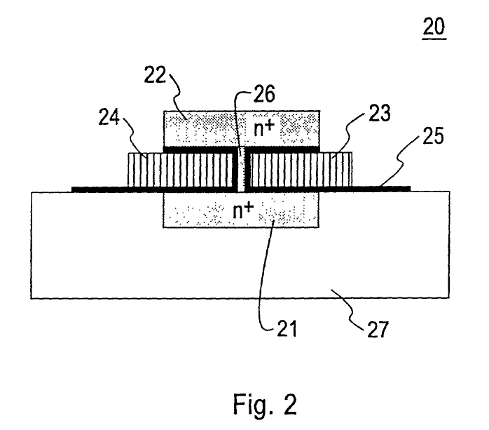

A vertical transport dual gate MOSFET 20, according to the present invention, is illustrated in FIG. 2. It is formed in a semiconductor substrate 27. In the present example, a first semiconductor region 21 is defined by n+ doping at least part of the substrate 27. The shape of this region may have any form. On top of this first semiconductor region 21, a thin and short semiconductor gate channel 26 is situated. The orientation of this channel 26 is perpendicular to the substrate 27. The channel 26 is in home-epitaxial alignment with said first region. A second semiconductor n+ doped region 22 is situated on top of this semiconductor gate channel 26. This second region 22 also is in home-epitaxial alignment. The vertical surfaces of the semiconductor gate channel 26, the upper surface of the first semiconductor region 21 and the lower surface of second semiconductor region 22 are covered by a thin gate oxide 25. The gate electrodes 23, 24 are formed between said first and second semiconductor regions 21, 22. These gate electrodes 23 and 24 are separated from the semiconductor gate channel 26 by said gate oxide layer 25. Either said first semiconductor region 21 serves as drain and said second semiconductor region 22 serves as source, or vice versa.

The above embodiment can be modified in various manners, as becomes obvious from the embodiments to follow. The n+ doped regions can be replaced by p+ doped regions, for instance. The size and shape of the heavily doped regions can be varied, the whole substrate could be a heavily doped substrate, just to mention some possible modifications.

Before turning to further embodiments, a method for making the device of FIG. 2 will be addressed in detail.

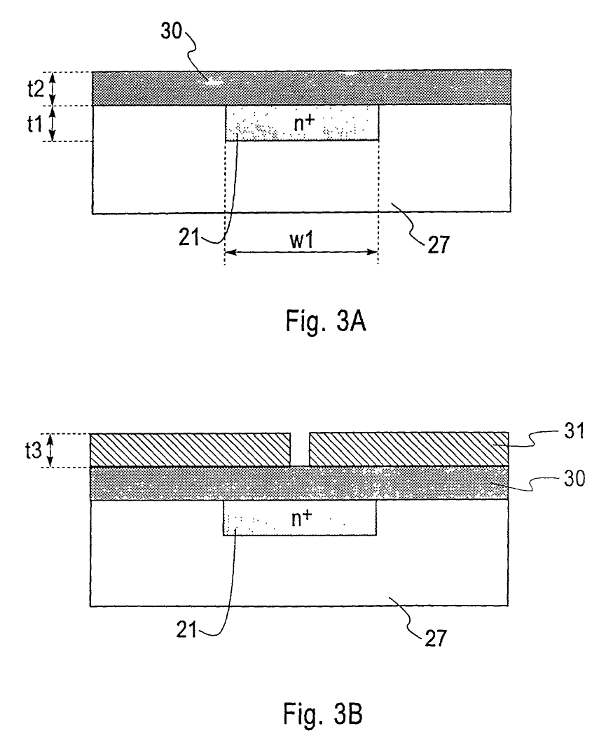

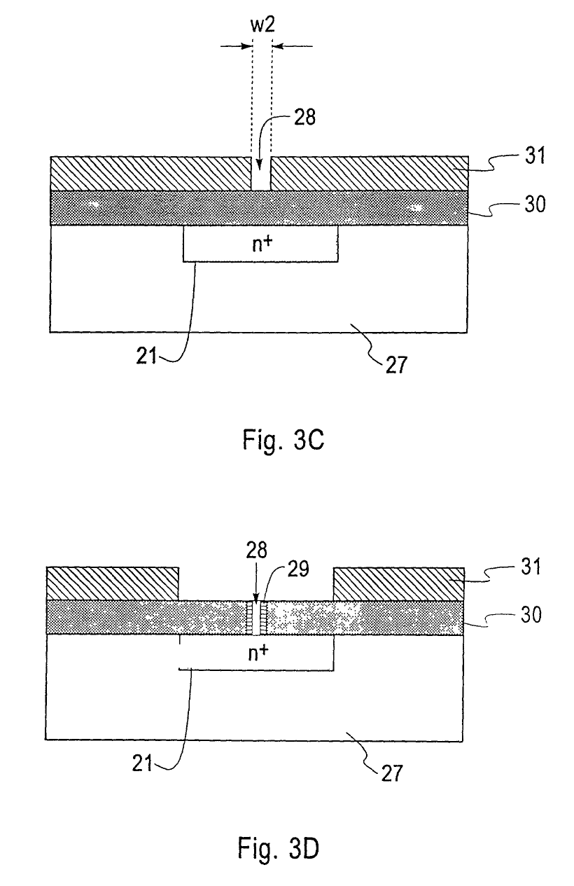

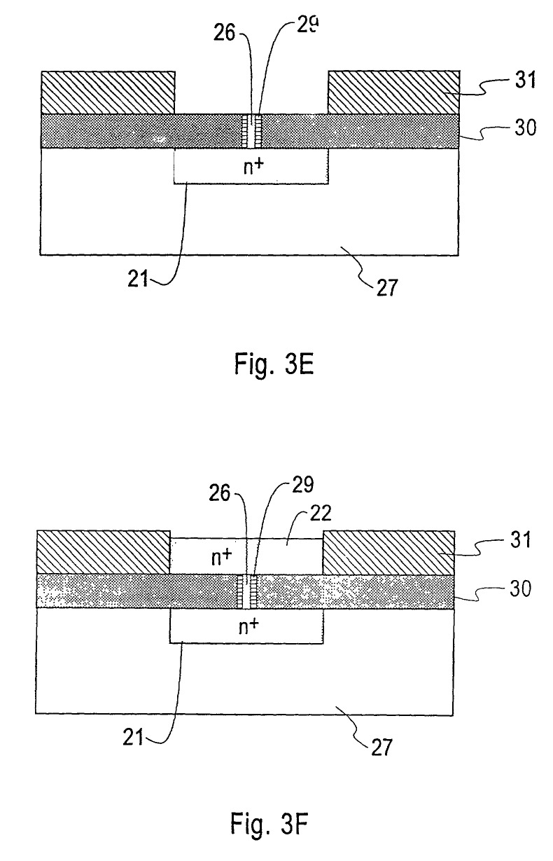

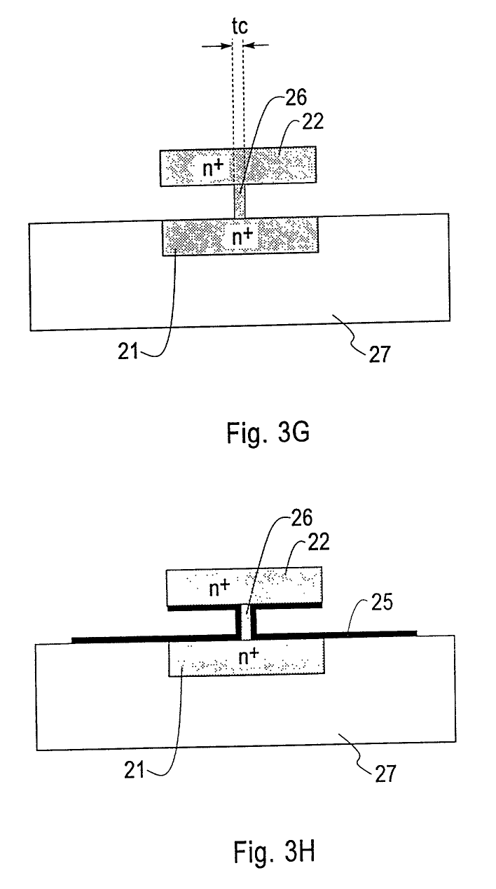

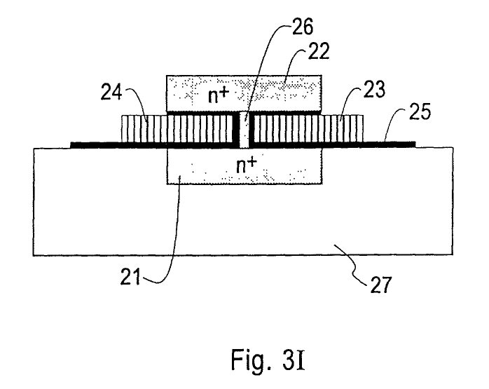

The respective method steps are described with reference to FIGS. 3A-3I. It is to be noted that these steps not necessarily have to be executed in the order illustrated and described.

In the present example, a vertical transport dual gate MOSFET is formed on a silicon substrate 27. This substrate 27 is prepared by definition of a heavily doped first semiconductor region 21, as illustrated in FIG. 3A. p-doped Silicon or Silicon-On-Insulator (SOI) may serve as substrate 27, for example. In the present example this region 21 comprises about 10 sup 20 dopants per cm sup 3. Well suited for n-type doping are: P, As and Sb, for example. For p-type doping B, In and Ga may be used.

In the present embodiment, the region 21 will serve as source electrode of the MOSFET. The dimensions of the first semiconductor region 21 are as follows: thickness (t1) between 20 nm and several hundreds of nm; width (w1) between 50 nm up to several μm; length (not shown) between 50 nm up to many microns.

Then, the substrate 27 is coated with a dielectric film 30. This film 30 at least covers the part of the substrate 27 in which the MOSFET is to be formed. The dielectric film 30 may consist of silicon dioxide (SiO sub 2) or silicon nitride (Si sub 3 N sub 4), for example. The thickness t2 of the dielectric layer 30 has to be approximately the same as the length of the gate channel to be formed.

As illustrated in FIG. 3B, the dielectric layer 30 is next covered by a structured mask layer 31. This mask layer 31 may be a dielectric layer, too. Likewise, a resist or metal could be used. The mask layer 31 may be between 10 nm up to several hundreds or nm thick (t3). Next, an etch window 28 (FIG. 3C) is defined in said dielectric layer 30. This etch window is preferably defined by a combination of lithography and reactive ion etching (RIE). At the bottom of this etch window 28 the first semiconductor region 21 is exposed, as illustrated in FIG. 3C. The width w2 of the etch window 28 should be close to the desired gate channel thickness tc, and the depths of the etch window 28 is defined by the thickness t2 of layer 30. The length of the etch window (the dimension out of the plane of the paper in FIG. 3C) should be close to the desired device length.

If the available lithographic processes used to make the etch window 28 are not suited of imaging the etch window to the desired width, the etch window 28 may be narrowed down by the use of an optional sidewall formation process, as illustrated in FIG. 3D. Such sidewall formation processes are commonly used on gates of conventional lateral MOS transistor devices. In FIG. 3D, the sidewalls 29 are schematically illustrated. The sidewalls 29 may be made by deposition of a thin dielectric material, such as SiO₂ or Si₃N₄, for example. After narrowing down the sidewalls of the etch window 28, the desired channel thickness tc is precisely defined.

The gate channel is then formed, as illustrated in FIG. 3E, by filling the etch window 28 with a suited semiconductor material. In the present example, the gate channel is grown by selective epitaxy of silicon to form a channel in homo-epitaxial alignment with said first region 21. Preferably, undoped (intrinsic) silicon is used as gate channel. The epitaxy can be controlled such that the silicon only grows on the exposed area of the first semiconductor 21, and not on the surfaces of the dielectric film(s) 29, 30, 31. This is possible if one controls the temperature and gas conditions in the silicon growth apparatus. Instead of using an undoped channel, the channel may be doped using B or In if used in an n-FET, or it may be doped using P, As, or Sb if used in a p-FET.

In a next step, a second semiconductor region 22 may be formed on top of the semiconductor gate channel 26, as illustrated in FIG. 3F. Said second semiconductor region 22 partially overlaps the dielectric layer 30. It can be grown epitaxially from the gate channel 26 and is in homo-epitaxial alignment. In the present example, the actual size of the second semiconductor region 22 is defined by the mask layer 31. The second semiconductor region 22 is n+ doped if the first semiconductor region 21 is n+ doped, and p+ doped if the latter would be p+ doped. The same dopants can be used for the first and second semiconductor regions. Also the dimensions of the first and second region may be the same. When doping the second semiconductor region 22, care has to be taken that dopants from this heavily doped region 22 are not incorporated into the gate channel 26. It should also be considered that no dopants diffuse into the gate after having been implanted. The second semiconductor region 22 may be doped in-situ, during the epitaxial growth, or subsequently, by another doping process, such as ion implantation or diffusion from a gas or solid source.

Following epitaxial growth, the dielectric layer 30 and the mask layer 31 are removed, as shown in FIG. 3G. Furthermore, the dielectric layer 29, if any, are to be removed from the sidewalls of channel 26. This can be done by selective etching, for example. After this step, said gate channel 26 and the surfaces of the first and second semiconductor regions 21, 22 facing each other become accessible (see FIG. 3G).

Now, a thin oxide layer 25 is formed, as shown in FIG. 3H. The portion of this oxide layer 25 which is formed on the vertical surface of the gate channel 26 serves as gate oxide. The portion of layer 25 which covers said heavily doped regions 21 and 22 will serve as spacer between the gate electrode(s) to be formed and the heavily doped regions 21 and 22. This portion of the layer 25 which covers the heavily doped regions usually is thicker than the portion formed on the sidewalls of the channel 26. The thickness of layer 25 typically is between 1 nm-5 nm. SiO₂, for example, may serve as gate oxide 25.

Next, the gate electrodes 23, 24 are formed, as illustrated in FIG. 31, such that they are separated from the gate channel by the oxide layer 25 serving as gate oxide. The gate electrode(s) 23, 24 can be deposited by chemical vapor deposition (CVD), for example. Polysilicon (doped with P or B, 10¹⁸/cm³), or Tungsten or Aluminum can be used as electrode material, for example. In another step, a metallization pattern may be formed that allows to contact source 21, drain 22, and the two gate electrodes 23 and 24 (please note that this metallization pattern is not shown). One may, for example, deposit an electrode layer which is patterned using lithography and RIE to form the gate electrodes 23, 24, and the metallization pattern not illustrated. Part or all of this metallization pattern may be formed in the third dimension (out of the plane of the paper). The contacts to source, drain and gates may be formed using standard contact materials.

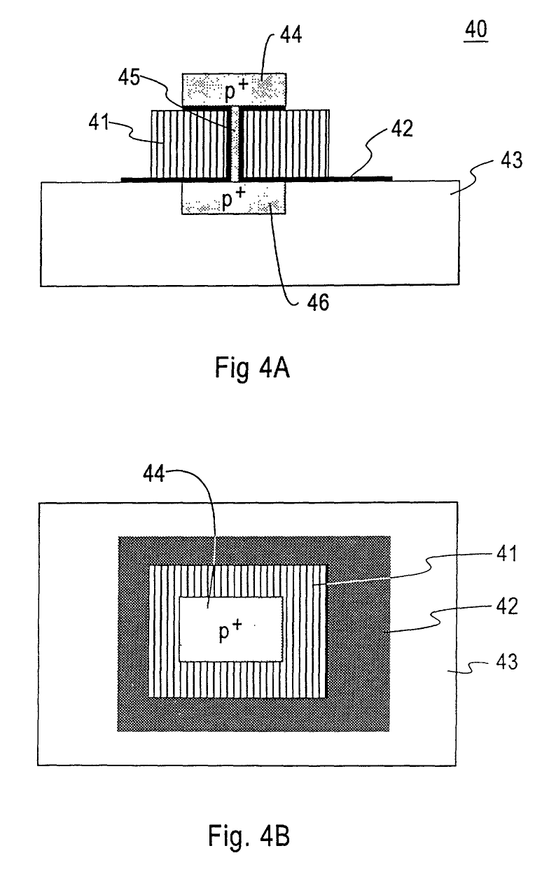

A schematic top view of another embodiment of the present invention is illustrated in FIG. 4, where FIG. 4A shows a schematic cross-section and 4B a schematic top view. The vertical transport gate MOSFET 40 in FIG. 4 is mainly characterized in that it only has one gate electrode 41. This gate electrode 41 completely surrounds the gate channel 45. Only part of the substrate 43 is covered by the thin oxide layer 42. The gate electrode 41 is thus isolated from the substrate 42 and the heavily p-doped first semiconductor region 46 serving as drain. The heavily p-doped second semiconductor region 44 which serves as source, is situated on top of the gate electrode 41. As indicated in FIG. 4A, the source and drain do not necessarily have to have the same size and shape. The complete substrate may for example be heavily doped, instead of a smaller portion thereof.

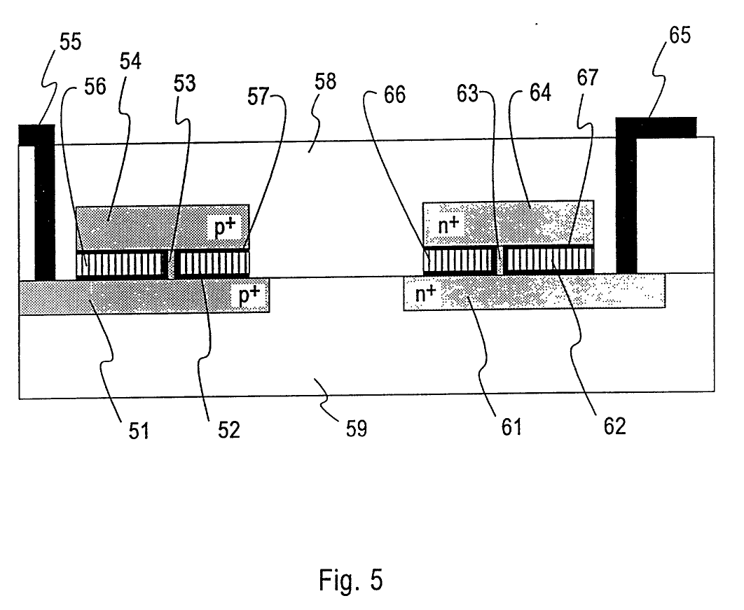

A cross section of a CMOS implementation 50 of two vertical transport dual gate MOSFETs, according to the present invention, is illustrated in FIG. 5. Shown is a n-type MOSFET (on the right hand side) adjacent to a p-type MOSFET (on the left hand side). Both MOSFETs are implemented in the same substrate 59. The n-type MOSFET comprises a heavily n-doped first semiconductor region 61, a thin and short semiconductor gate channel 63 being oriented perpendicular with respect to the first semiconductor region 61. In addition, two gate electrodes 62 and 66, a thin gate oxide 67, and a heavily n-doped second semiconductor region 64 are provided.

The p-type MOSFET comprises a heavily p-doped first semiconductor region 51, a thin and short semiconductor gate channel 53 being oriented perpendicular with respect to the first semiconductor region 51, two gate electrodes 52 and 56, a thin gate oxide 57, and a heavily p-doped second semiconductor region 54. A first metallization pattern 55 is shown, which allows to contact the p+-doped first semiconductor region 51, and a second metallization pattern 65 is shown, which allows to contact the n+-doped first semiconductor region 61. Both MOSFETs are covered by a dielectric layer 58, such as a silicon nitride layer, for example.

The inventive MOSFET structures described above incorporate one or two gate electrodes and an ultrathin gate channel. The structures can be scaled beyond the limits of 30 nm gate length and 5 nm channel thickness. The key features and advantages are:

a vertical transport arrangement with one or two sidewall gate electrodes;

this particular arrangement requires less real estate per MOSFET, i.e., higher integration densities can be achieved;

the active area of the MOSFETs is determined by a single level of high resolution lithography;

all other key features of the MOSFETs can be fabricated by a combination of thin film deposition, growth, etching and oxidation, so that the devices are entirely self-aligned.

the ultrathin channel can be formed by selective epitaxial growth;

the source/channel and drain/channel junctions may be very tightly controlled, as they are determined by dopant distribution in the vertical direction.

p-type and n-type MOSFETs with one or two gate electrodes can be easily implemented in a common substrate;

MOSFETs according to the present invention can be used in many different kinds of circuits, such as high performance logic, low power logic or high density memory devices. They can easily be combined with other elements, such as for example capacitors, resistors, diodes, memory cells and so forth. Because of their small size and ease of fabrication, the present MOSFETs are also suited for use in connection with organic displays or liquid crystal displays (LCDs).

1. A metal oxide semiconductor field effect transistor (MOSFET) comprising:
a first semiconductor region formed in a semiconductor substrate, said region being defined in said semiconductor substrate by n+-type doping or p+-type doping,
a thin and short semiconductor channel being arranged perpendicular with respect to said substrate, said channel being in homo-epitaxial alignment with said first semiconductor region,
a gate oxide layer formed on the sidewalls of semiconductor channel,
a second semiconductor region formed at the opposite end of said semiconductor channel, said region being n+ doped if said first semiconductor region is n+ doped, or p+ doped if said first semiconductor region is p+ doped, said second semiconductor region being in homo-epitaxial alignment with said semiconductor channel,
at least one gate electrode arranged between said first and second semiconductor regions such that it is separated from said semiconductor channel by a gate oxide layer,
said first semiconductor region serving as drain and said second semiconductor region serving as source, or vice versa.

2. The transistor of claim 1, wherein said substrate comprises p+-doped silicon.

3. The transistor of claim 1, wherein said substrate is a silicon-on-insulator substrate (SOI).

4. The transistor of claim 1, wherein said first and second semiconductor regions if being n+-doped comprise either one or any combination of the following dopants: P, As, Sb.

5. The transistor of claim 1, wherein said first and second semiconductor regions if being p+-doped comprise either one or any combination of the following dopants: B, In, Ga.

6. The transistor of claim 1, wherein said semiconductor channel comprises undoped silicon.

7. The transistor of claim 1, being an n-FET.

8. The transistor of claim 1, being a p-FET.

9. The transistor of claim 7, wherein said semiconductor channel comprises silicon being doped with B, or In, or B and In.

10. The transistor of claim 8, wherein said semiconductor channel comprises silicon being doped with P, or As, or Sb, or any combination thereof.

11. The transistor of claim 1, wherein said gate electrode comprises polysilicon, or tungsten, or aluminum.

12. A semiconductor device comprising at least two transistors according to claim 1.

13. A semiconductor device comprising at least one transistor according to claim 7 and one transistor according to claim 8.

14. The semiconductor device of claim 12 or 13, in addition comprising at least one of the following elements: capacitor, resistor, diode, memory cell.

15. Method for making a metal oxide semiconductor field effect transistor (MOSFET), comprising the steps:
defining a first semiconductor region in a substrate by n+-type or p+-type doping,
covering at least part of said first semiconductor region by a first layer the thickness of which approximately defines the length of a semiconductor channel to be formed,
defining an etch window in said first layer, the width of which corresponds to the thickness and the depth of which corresponds to the length of said semiconductor channel to be formed,
forming said semiconductor gate channel by filling up said etch window with a semiconductor such that said channel is in homo-epitaxial alignment with said first semiconductor region,
forming an n+-doped second semiconductor region on top of said semiconductor channel if said first semiconductor region is n+-doped, or forming a p+-doped second semiconductor region on top of said semiconductor channel if said first semiconductor region is p+-doped, said second semiconductor region partially overlapping said first layer and being in homo-epitaxial alignment with said semiconductor channel,
removing at least part of said first layer such that said semiconductor channel and the surfaces of said first and second semiconductor regions which face each other become accessible,
forming a thin gate oxide covering the vertical surface of said semiconductor channel and at least part of the horizontal surfaces of said first and second semiconductor regions facing each other,
forming at least one gate electrode such that it adjoins to said gate oxide.

16. The method of claim 15, wherein a mask layer is formed on said first layer prior to defining said etch window in said first layer, a window being formed in said mask layer and this window being transferred into said first layer by means of etching.

17. The method of claim 15, wherein sidewall formation process is employed to narrow down said etch window being formed in said first layer.
